(19) United States
(12) Patent Application Publication
(10) Pub. No.: US 2008/0093690 A1
(43) Pub. Date: Apr. 24, 2008

(54) Micromechanical component having a monolithically integrated circuit and method for manufacturing a component

(76) Inventors: Frank Reichenbach, Wannweil (DE); Franz Laermer, Weil Der Stadt (DE); Kersten Kehr, Zwota (DE); Axel Franke, Ditzingen (DE); Andreas Scheurle, Schwaebisch Gmuend (DE)

Correspondence Address: KENYON & KENYON LLP, ONE BROADWAY, NEW YORK, NY, 10004, US

(21) Appl. No.: 11/974,011

(22) Filed: Oct. 10, 2007

(30) Foreign Application Priority Data
Oct. 19, 2006 (DE) 10 2006 049 256.0
Nov. 8, 2006 (DE) 10 2006 052 630.9

(51) Int. Cl. H01L 29/84; H01L 21/302

(52) U.S. Cl. 257/415; 438/50; 257/E21.214; 257/E29.324

(57) ABSTRACT

A micromechanical component and a method for manufacturing such a component, the component having a micromechanical structure and an integrated circuit, the micromechanical structure being monolithically integrated into the circuit, the circuit being provided in a circuit area of the substrate, and the micromechanical structure being provided in a sensor area of the substrate, the material of the substrate being provided in the area of a sacrificial layer as well as in the area of a function layer without a transition.

### FIELD OF THE INVENTION

The present invention is directed to a micromechanical component.

### BACKGROUND INFORMATION

German Patent Application DE 103 48 908 A1 discusses a microsystem having an integrated circuit and a micromechanical component. A microsystem having an integrated circuit is discussed, although the wafer material of the substrate wafer is provided as sacrificial layer areas here, the sacrificial layer areas to be removed must always be separated by an isolating oxide area and/or an isolating oxide layer from the substrate material that is not to be removed. This results in a comparatively expensive method of manufacturing such a known microsystem. Furthermore, this manufacturing method is comparatively time-consuming, thereby also resulting in cost disadvantages due to additional manufacturing steps. In addition, the sacrificial layer may be made of another material, e.g., silicon oxide, that is different from the material of the function layer—e.g., epitaxially grown polycrystalline silicon material—and the sacrificial layer may be removed by using hydrofluoric acid from the gas phase, for example. However, monolithic circuit integration may be either very difficult or impossible in this case.

### SUMMARY OF THE INVENTION

The micromechanical component according to the present invention and the method for manufacturing a micromechanical component according to the other main patent claims has the advantage that they overcome or at least minimize the disadvantages of the related art and permit a comparatively compact micromechanical structure having a monolithically integrated circuit, in particular an analyzer circuit, to be inexpensively manufacturable.

Thus, according to the exemplary embodiments and/or exemplary methods of the present invention, it is possible for the component according to the present invention to be usable inexpensively as an acceleration sensor, in which case sensors for both linear acceleration and rotational acceleration and/or yaw rates may be considered here. Due to the fact that the material of the substrate is provided without a transition in the area of the sacrificial layer as well as in the area of the function layer, it is not necessary here to provide isolating structures, e.g., isolating oxides, in the substrate material and to structure them. The etching process to remove the sacrificial layer is terminated at least partially in a time-controlled manner according to the exemplary embodiments and/or exemplary methods of the present invention, so that an etch stop structure need not necessarily be provided in the substrate material.

According to the exemplary embodiments and/or exemplary methods of the present invention, an insulation structure may be provided, in particular a trench structure filled with an insulation layer, between the circuit area and the sensor area. In this way, it is advantageously possible according to the exemplary embodiments and/or exemplary methods of the present invention to achieve good electrical insulation of the sensor area from the circuit area without performing a prestructuring of the substrate wafer into the depth of the substrate.

Furthermore, according to the exemplary embodiments and/or exemplary methods of the present invention, the main extension plane of the substrate may be parallel to a 100-crystal face. In this way it is possible to achieve a particularly good lateral etching, i.e., undercutting of the structures to be exposed, without excess etching in a direction perpendicular to the main extension plane of the substrate.

Also, according to the exemplary embodiments and/or exemplary methods of the present invention, the function layer may be provided at least partially as a self-supporting micromechanical structure. In this way, it is advantageously possible according to the exemplary embodiments and/or exemplary methods of the present invention to manufacture any micromechanical structures, in particular sensor structures for acceleration sensors or the like, using monolithic integration of a circuit.

Another subject matter of the exemplary embodiments and/or exemplary methods of the present invention is a method for manufacturing a component according to the present invention, in a first step an integrated circuit being at least partially processed in a circuit area; in a second step, a masking layer is applied to the circuit area as well as to the sensor area; in a third step, deep anisotropic etching is performed to structure the sensor area, and in a fourth step, a dry plasmaless second etching is performed to remove the sacrificial layer. In this way it is possible according to the exemplary embodiments and/or exemplary methods of the present invention to implement a high-performance sensor component using a comparatively simple process sequence with minimal effort, in particular without manufacturing isolating oxides within the sensor area.

It is particularly advantageous that the sensor structures within the sensor area may be manufactured from monocrystalline silicon, known as bulk silicon, i.e., the substrate material itself by the surface micromechanical technique. Use of the dry plasmaless second etching to remove the sacrificial layer, which is provided without a transition to the function layer, has the advantage that the sensor structures within the sensor area may be dissolved directly out of the bulk silicon by undercutting and therefore no layered structure of sacrificial layer and function layer (with corresponding layer transitions) is necessary. In addition, the second etching is ideal for integrating the manufacturing process for manufacturing the sensor into the manufacturing process for production of the circuit, and according to the exemplary embodiments and/or exemplary methods of the present invention, it does not matter whether the circuit process is a CMOS (complementary metal oxide semiconductor) process or a BCD (bipolar CMOS-DMOS process) process using an epitaxial layer.

Therefore, according to the exemplary embodiments and/or exemplary methods of the present invention, deep anisotropic etching may be performed essentially completely through unstructured material of the substrate, in particular material that has been simply doped and in which there are no isolating oxide layers or similar structures, for example.

Use of CIF₃ etching as the second etching may be particularly preferred here, with the etching being performed in particular at substrate temperatures of less than or equal to approximately −10° C., which may be at substrate temperatures of approximately −30° C. to approximately −10° C. In this way there is no anisotropy in this etching process, which is advantageously used according to the exemplary embodiments and/or exemplary methods of the present invention to etch to a greater extent laterally than in depth. This has the special advantage that the undersides of the structure that are to be exposed by the second etching may be defined very well as virtually planar surfaces, thus avoiding the characteristic uneven undercutting profiles of isotropic etchings for the removal of sacrificial layers.

At a point in time before the first step or between the first and second steps, an insulation layer, in particular a trench structure filled with an insulation layer, may be introduced into the substrate between the sensor area and the circuit area and/or if the substrate in the sensor area is doped at a point in time before the first step. In this way the sensor structure may be situated so that it is electrically insulated from the circuit area and the individual areas of the sensor structure may be provided so that they are electrically conductive.

Exemplary embodiments of the present invention are depicted in the drawing and described in greater detail in the following description.

### BRIEF DESCRIPTION OF THE DRAWINGS

FIG. 1 shows a schematic sectional diagram of precursor structure(s) of a component according to the exemplary embodiments and/or exemplary methods of the present invention.

FIG. 2 shows another schematic sectional diagram of precursor structure(s) of a component according to the present invention.

FIG. 3 shows another schematic sectional diagram of precursor structure(s) of a component according to the present invention.

FIG. 4 shows another schematic sectional diagram of precursor structure(s) of a component according to the present invention.

FIG. 5 shows another schematic sectional diagram of precursor structure(s) of a component according to the present invention.

FIG. 6 shows another schematic sectional diagram of precursor structure(s) of a component according to the present invention.

FIG. 7 shows another schematic sectional diagram of precursor structure(s) of a component according to the present invention.

FIG. 8 shows another schematic sectional diagram of precursor structure(s) of a component according to the present invention.

FIG. 9 shows another schematic sectional diagram of precursor structure(s) of a component according to the present invention.

FIG. 10 shows another schematic sectional diagram of precursor structure(s) of a component according to the present invention.

FIG. 11 shows another schematic sectional diagram of precursor structure(s) of a component according to the present invention.

FIG. 12 shows another schematic sectional diagram of precursor structure(s) of a component according to the present invention.

FIG. 13 shows another schematic sectional diagram of precursor structure(s) of a component according to the present invention.

FIG. 14 shows a schematic sectional diagram of a component according to the present invention manufactured by the manufacturing method according to the present invention.

### DETAILED DESCRIPTION

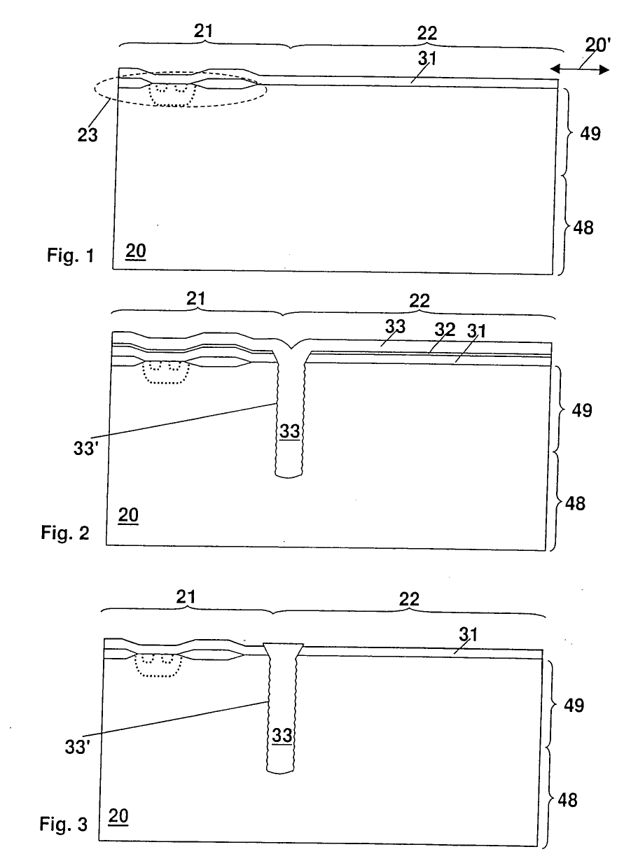

FIGS. 1 through 13 each show a schematic sectional diagram of precursor structures of a component 10 according to the present invention, and FIG. 14 shows a schematic sectional diagram of component 10.

FIG. 1 illustrates a first precursor structure. A substrate 20, which is provided in particular as a silicon substrate 20, e.g., monocrystalline silicon material, has a circuit area 21 and a sensor area 22. The main extension plane of substrate 20 is labeled as 20′.

Circuit area 21 includes various structures, e.g., doping regions or deposits, which should indicate a circuit structure (e.g., a transistor or the like). These structures are all labeled with reference numeral 23 and are shown as being outlined by a dashed line (but not yet included in the other figures for the sake of simplicity). Within the scope of the exemplary embodiments and/or exemplary methods of the present invention, it essentially does not matter whether the manufacturing method for creating the circuit is a CMOS (complementary metal oxide semiconductor) process or a DMOS (double diffused metal oxide semiconductor) process or a bipolar process or a so-called BCD (bipolar CMOS-DMOS) process. The deciding factor is that the available temperature budget for manufacturing the structures of sensor area 22 is comparatively small after completion of essential steps of the circuit process, which restricts the options for structuring in the sensor area. The exemplary embodiments and/or exemplary methods of the present invention is depicted below on the example of a CMOS circuit structure and/or a so-called HCMOS structure (high-voltage CMOS).

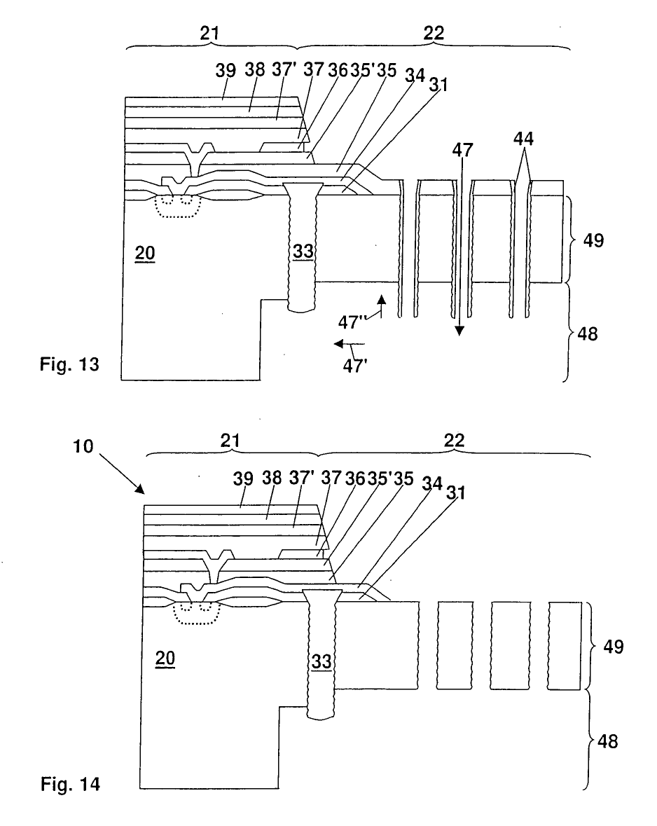

Structuring of sensor area 22 is performed toward the end of processing of circuit area 21 (so-called back-end integration of sensor structuring). Structuring of sensor area 22 (see FIGS. 13 and 14) results in a division of substrate 20 into a sacrificial layer 48 and a function layer 49. However, according to the exemplary embodiments and/or exemplary methods of the present invention, before performing the manufacturing steps for circuit area 21 it is necessary that sensor area 22 which is offset laterally with respect to circuit area 21 has a sufficiently high level of doping to ensure the conductivity of the sensor structures, which is usually desired within sensor area 22.

This doping of sensor area 22 may be performed according to the exemplary embodiments and/or exemplary methods of the present invention before the circuit process and/or the ASIC process (for structuring circuit area 21). When using CIF₃ as the gaseous etchant (to remove sacrificial layer 48), the etching performance depends very little on the doping of the semiconductor material, so essentially almost any doping of sensor area 22 with electron donors (n-type doping) or electron acceptors (p-type doping) is possible according to the exemplary embodiments and/or exemplary methods of the present invention. It is particularly advantageous that p-doped or p++-doped material is used as the material of function layer 49 because this doping slightly slows down the etching attack by CIF₃ gaseous etchant until achieving a reduction by a factor of approximately 2.

According to the exemplary embodiments and/or exemplary methods of the present invention, it is provided that no buried structures are provided and/or necessary to implement the differentiation between sacrificial layer 48 and function layer 49, but instead the material of substrate 20 (as is visible in FIG. 1) is provided in the area of sacrificial layer 48 as well as in the area of function layer 49 without a transition. FIG. 1 illustrates the manufacturing method for circuit area 21 using the example of an HCMOS circuit process just before a so-called first metal plane. It is essential that the process steps of the circuit process that are critical in terms of contamination and fabrication are completed. A first passivation layer 31 is provided as a so-called BPSG layer (boron-phosphorus-silicate glass layer), for example, but as an alternative, it may also be a passivation layer of another material.

FIG. 2 shows a second precursor structure in a schematic sectional diagram. A second passivation layer 32, in particular a PECVD nitride material, is deposited as a so-called buffer layer on first passivation layer 31. First and second passivation layers 31, 32 are then opened by using a lacquer mask, and a trench etching step is formed [sic] to create an insulation trench 331, i.e., an insulation structure 33′. Insulation trench 33′ is filled with a third passivation layer 33.

FIG. 3 shows a schematic sectional diagram of a third precursor structure in which third passivation layer 33 has been removed down to second passivation layer 32, which may be by using a planarization etching step, and in which second passivation layer 32 has subsequently also been removed. The third precursor structure thus again achieves the starting state according to the first precursor structure with regard to circuit area 21, with only the insulation trenches being inserted. Insulation structure 33′ creates the insulated suspension of the individual sensor electrodes. To do so, according to the exemplary embodiments and/or exemplary methods of the present invention, insulation trenches 33′ are to be introduced into substrate 20 prior to the circuit process (not shown) or at a suitable location in the circuit process.

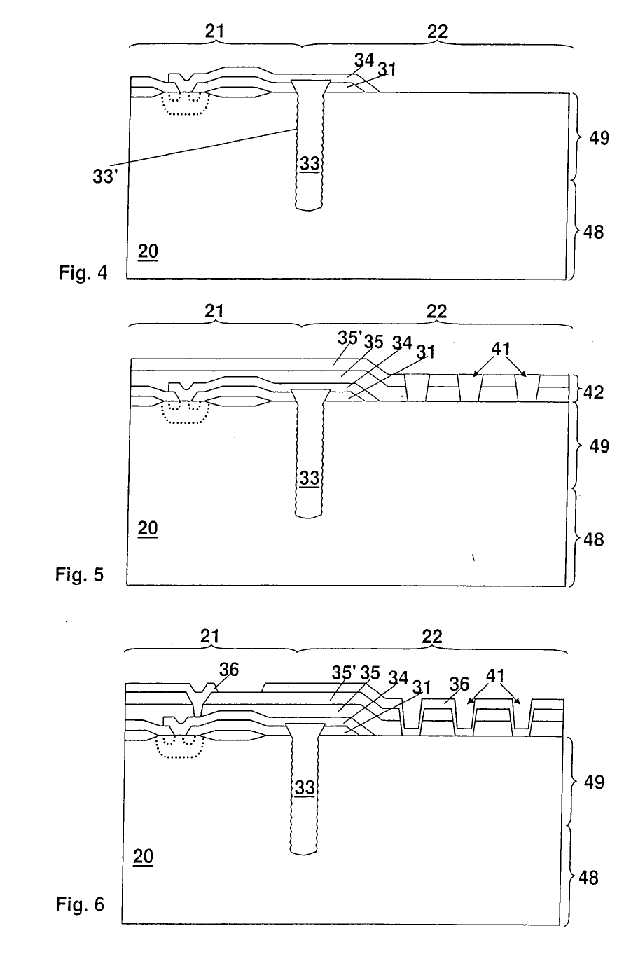

FIG. 4 shows a schematic sectional diagram of a fourth precursor structure in which a first metal layer 34, which is provided in the circuit process, is used to form a contact between the circuit area 21 and sensor area 22 by appropriate structuring, and thus the contacting of sensor area 22 is integrated into the circuit process. Insulation trenches 33′ should be filled with the least possible topography (i.e., the smallest possible vertical variation) because after being exposed, the sensor structures (see FIG. 13) are mechanically attached to insulation trenches 33′ and are suspended in a stable manner on so-called “mainland” (in particular in the form of a circuit area 21 completely surrounding sensor area 22) and at the same time the contact of the sensor structures and/or sensor electrodes over insulation trenches 33′ must be ensured. To do so, insulation trenches 33′ may be filled with TEOS/ozone oxide (i.e., a silicon oxide material) as third passivation layer 33, which is deposited in a plasmaless process, for example. To reduce the topography, the oxide layer (i.e., third passivation layer 33) should be leveled by lacquering and planarizing etching. Buffer layer 32, which acts as an etch stop and may then be removed selectively down to the underlying layer (first passivation layer 31), is used therefor in particular.

FIG. 5 shows a schematic sectional diagram of a fifth precursor structure, in which a fourth and then a fifth passivation layer 35, 35′ (in particular as silicon oxide, which may be as a so-called TEOS oxide) are deposited on circuit area 21 as the dielectric (as part of the circuit process). Fourth and/or fifth passivation layers 35, 35′ having structuring 41 (recesses) form a so-called hard mask 42 in sensor area 22, which defines the locations at which access to the undercutting of function layer 49 is created within sensor area 22.

FIG. 6 shows a schematic sectional diagram of a sixth precursor structure in which a second metal layer 36 (possibly having a so-called via structure (through-hole and/or contacting connection) 36′ to first metal layer 34) is deposited, this metal layer being part of the circuit process. In sensor area 22, this second metal layer 36 functions as a protection for hard mask 42 in a subsequent etching step (see FIG. 8).

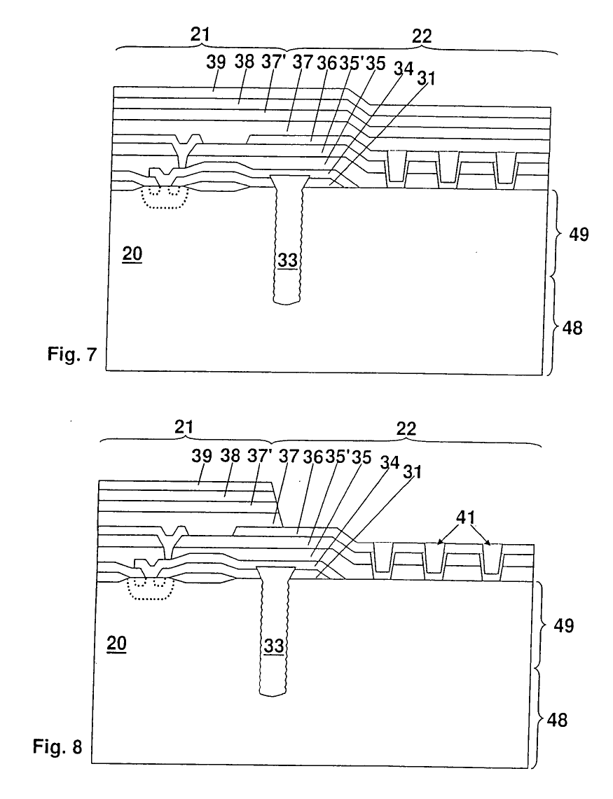

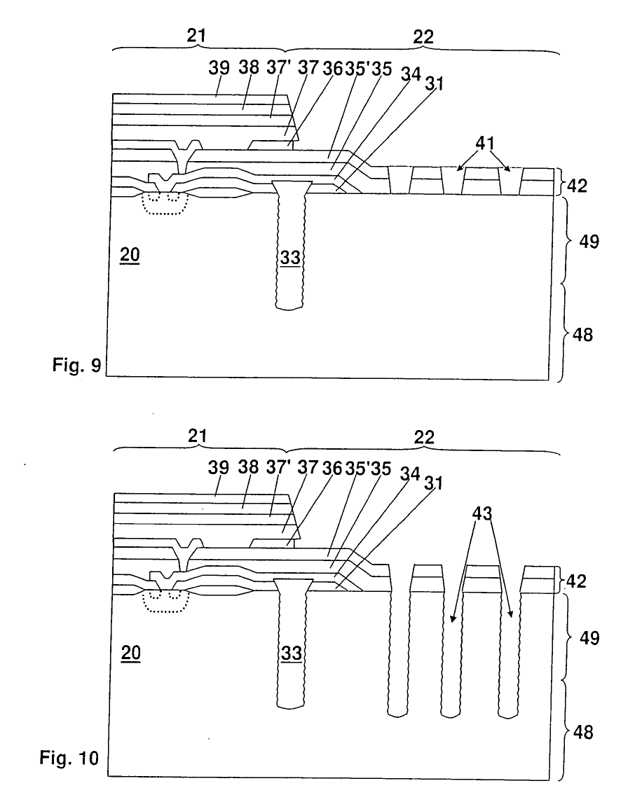

FIG. 7 shows a schematic sectional diagram of a seventh precursor structure, in which a sixth and then a seventh passivation layer 37, 37′ are deposited as a dielectric in circuit area 21 (as part of the circuit process). In addition, a third metal layer 38 (possibly having a via structure, not shown, to second metal layer 36) and an eighth passivation layer 39 are also deposited. The layers deposited in the seventh precursor structure (FIG. 7) are subsequently etched back in sensor area 22 in an eighth precursor structure (FIG. 8), with second metal layer 36 functioning as an etch stop layer. In the case of a ninth precursor structure (FIG. 9), this second metal layer 36 is also etched away in sensor area 22, exposing hard mask 42, which is then open for an etching attack in its exposed areas (structuring 41).

According to the exemplary embodiments and/or exemplary methods of the present invention, a dielectric layer is deposited from the process for manufacturing the circuit, e.g., the TEOS oxide layer shown here, between first metal layer 34 and second metal layer 36 in the HCMOS process for a hard mask 42. If this hard mask 42 is provided with an etch stop layer (such as second metal layer 36), then hard mask 42 may also be selectively exposed after completion of the circuit.

FIG. 10 shows a schematic sectional diagram of a tenth precursor structure. In the tenth precursor structure, trench structures have been created in substrate 20 of sensor area 22 by deep anisotropic etching 43. A so-called DRIE (deep reactive ion etching) process may be used in deep anisotropic etching. According to the exemplary embodiments and/or exemplary methods of the present invention, a so-called RIE lag may be prevented (this is understood to refer to the effect whereby narrow trenches (having a high aspect ratio) are etched more slowly than wide trenches because of the depletion of the etching medium).

British patent document GB 2341348A and U.S. Pat. No. 6,303,512 are herewith introduced as reference documents regarding the precise conditions with regard to conducting a so-called trench etching process. By using the so-called Bosch process described in German patent document DE 42 41 045 and/or U.S. Pat. No. 5,501,893 and/or European patent document EP 0 625 285 (thanks to the independently controlled etching and passivation steps) it is possible in deep vertical etching of silicon to achieve almost complete RIE lag compensation by being able to adjust the lag effects of both the etching and passivation steps through the process pressures of the individual steps, which are selected individually and independently of one another, and through the wafer temperature so as to yield a net compensation effect.

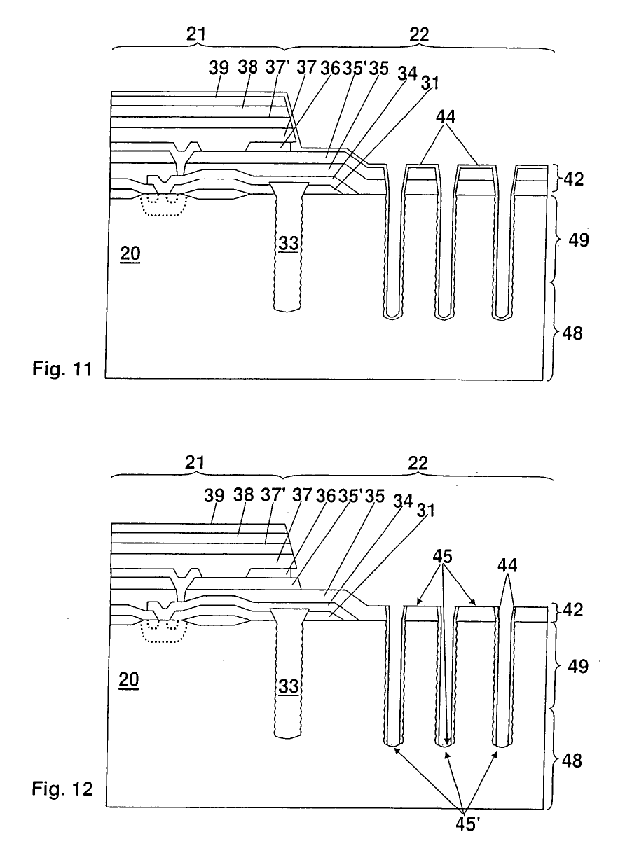

Manufacturing of sensor structures in sensor area 22 without buried structures and/or without buried layers (i.e., with a substrate material 20, which is provided between sacrificial layer 48 and function layer 49 without a transition) is possible when another passivation layer 44 is deposited after the trench process, i.e., deep etching 43, so that it conforms to all the trenched structures (i.e., provided with trenches) in sensor area 22. This is shown in the schematic sectional diagram in FIG. 11 in the form of an eleventh precursor structure. FIG. 12 shows a schematic sectional diagram of a twelfth precursor structure, showing that this additional passivation layer 44 may be etched back by an additional anisotropic etching 45 at the bottom 45′ of the trench structures, so that at this location there is clear access to sacrificial layer 48 for the second etching.

If a sufficiently thick hard mask 42 is used and is not completely removed during the trench etching process (deep etching 43), then the structures are protected, i.e., passivated at the top (due to the remaining hard mask) after the additional anisotropic etching step and at the side walls (due to the additional passivation layer 44, which may be in particular an oxide material such as silicon oxide or a Teflon material and/or a Teflon-like material) during a subsequent second etching step 47 and/or a second etching 47 and only bottoms 45′ of the trench structures are opened. Therefore, additional passivation layer 44 is also referred to below as side wall passivation 44. Second etching 47 begins there in vertical and lateral directions, opening sacrificial layer 48 and exposing the sensor structures, as illustrated in FIG. 13.

FIG. 13 shows a schematic sectional diagram of a thirteenth precursor structure in which second etching 47 has been performed and etching has been performed in lateral direction 47′ and in vertical direction 4711 to remove sacrificial layer 48 starting from former bottoms 45′ of the trench structures. If CIF₃ is used as the gaseous etchant for the second etching (so-called release etching), then any silicon oxide that is deposited in a sufficiently conforming manner may be used for side wall passivation 44. CIF₃ etches silicon in all directions with a high selectivity to silicon oxide, Teflon and Teflon-like layers and other dielectrics, and a pronounced crystal direction anisotropy, i.e., a dependence of the etching speed, in particular the undercutting speed, on the particular direction in the silicon single crystal, prevails under suitably selected process conditions (e.g., at a wafer temperature lower than or equal to approximately −10° C.).

Therefore, according to the exemplary embodiments and/or exemplary methods of the present invention, such process conditions are particularly suitable for exposing the structures in sensor area 22 in a controlled manner with a high reproducibility while at the same time maintaining almost planar undersides of the structures when they run parallel to 100-crystal faces, for example (i.e., the main extension plane of substrate 20 is parallel to such a 100-crystal face). Thus, according to the exemplary embodiments and/or exemplary methods of the present invention, the typical undercutting profiles of a true anisotropic undercutting, which are harmful from a mechanical standpoint, are largely prevented, resulting in better mechanical properties of the resulting sensor component. CIF₃ as the gaseous etchant etches such faces running parallel to a 100-crystal direction at a much lower rate than faces running parallel to a 110-crystal direction.

According to the exemplary embodiments and/or exemplary methods of the present invention, the main extension direction 20′ of substrate 20 is selected to be parallel to the 100-crystal direction. In this case, the undersides of the structures as slow-etching faces are designed to be planar or comparatively planar in contrast with etching in the lateral direction (i.e., in contrast with undercutting), which may proceed particularly rapidly along the 110-crystal faces.

After exposing the micromechanical structure in sensor area 22, the passivation of hard mask 42 and side wall passivation 44 must also be removed to obtain the finished sensor component, i.e., finished micromechanical component 10, which is depicted in a schematic sectional diagram in FIG. 14. This removal of the side wall passivation should be performed in an etching step in gaseous hydrofluoric acid to prevent the structures from sticking to one another. However, etching in an aggressive HF vapor environment must be short enough to avoid damage to the circuit in circuit area 21. In side wall passivation of a few hundred nanometers, for example, this should still be ensured.

What is claimed is:

1. A micromechanical component having a substrate, comprising:
an integrated circuit;
a micromechanical structure, the micromechanical structure being provided so that it is monolithically integrated into the integrated circuit, the integrated circuit being provided in a circuit area of the substrate, and the micromechanical structure being provided in a sensor area of the substrate, wherein a material of the substrate is provided in an area of a sacrificial layer and in an area of a function layer without a transition.

2. The component of claim 1, wherein an insulation structure is provided between the circuit area and the sensor area.

3. The component of claim 1, wherein a main extension plane of the substrate is arranged parallel to a 100-crystal face.

4. The component of claim 1, wherein the function layer is provided at least partially as a self-supporting micromechanical structure.

5. A method for manufacturing a component, the method comprising:
(a) at least partially processing an integrated circuit in a circuit area;
(b) applying a masking layer to a circuit area and to a sensor area;
(c) performing a deep anisotropic etching for structuring the sensor area; and
(d) performing a dry plasmaless second etching to remove the sacrificial layer;
wherein a micromechanical component having a substrate is formed, the micromechanical component including:
the integrated circuit;
a micromechanical structure that is monolithically integrated into the integrated circuit, the integrated circuit being provided in the circuit area of the substrate, and the micromechanical structure being provided in the sensor area of the substrate, wherein a material of the substrate is provided in an area of a sacrificial layer and in an area of a function layer without a transition.

6. The method of claim 5, wherein the deep anisotropic etching is performed essentially completely through unstructured or doped material of the substrate.

7. The method of claim 5, wherein the second etching includes a CIF₃ etching, the etching being performed at substrate temperatures lower than or equal to approximately −10° C.

8. The method of claim 5, wherein at a point in time before (a) or between (a) and (b), an insulation structure or a trench structure filled with an insulation layer is introduced into the substrate between the sensor area and the circuit area.

9. The method of claim 5, wherein at a point in time before (a), the substrate is doped in the sensor area.

10. The method of claim 5, wherein the second etching includes a CIF₃ etching, the etching being performed at substrate temperatures of approximately −30° C. to approximately −10° C.

11. The component of claim 1, wherein an insulation structure, which includes a trench structure filled with an insulation layer, is provided between the circuit area and the sensor area.
